(19) United States
(12) Patent Application Publication
(10) Pub. No.: US 2014/0319594 A1
(43) Pub. Date: Oct. 30, 2014

(54) NONVOLATILE SEMICONDUCTOR STORAGE DEVICE AND METHOD OF MANUFACTURING THE SAME

(71) Applicant: Kabushiki Kaisha Toshiba, Minato-ku (JP)

(72) Inventor: Yuya MATSUDA, Yokkaichi (JP)

(73) Assignee: Kabushiki Kaisha Toshiba, Minato-ku (JP)

(21) Appl. No.: 14/087,386

(22) Filed: Nov. 22, 2013

(30) Foreign Application Priority Data
Apr. 24, 2013 (JP) 2013-091412

(51) Int. Cl. H01L 27/115; H01L 21/28; H01L 29/423

(52) U.S. Cl. CPC H01L 27/11517; H01L 29/42324; H01L 21/28273
USPC 257/316; 438/586

(57) ABSTRACT

A nonvolatile semiconductor storage device is disclosed including a semiconductor substrate; a gate insulating film formed above the semiconductor substrate; memory cell transistors formed above the gate insulating film, the memory cell transistors including a memory cell gate electrode, the memory cell gate electrode including a floating gate electrode having a first conductive film, an interelectrode insulating film, a control gate electrode having a stack of second conductive film and a metal film, and a first insulating film disposed one over the other; a sidewall film disposed so as to cover at least sidewalls of the metal film; and a second insulating film covering the memory cell gate electrode and the sidewall film.

### CROSS-REFERENCE TO RELATED APPLICATION(S)

This application is based upon and claims the benefit of priority from Japanese Patent Application No. 2013-091412, filed on, Apr. 24, 2013 the entire contents of which are incorporated herein by reference.

### FIELD

Embodiments disclosed herein generally relate to a nonvolatile semiconductor storage device and method of manufacturing the same.

### BACKGROUND

Nonvolatile semiconductor storage devices such as a NAND flash memory is provided with memory cell transistors. The gate electrode of the memory cell transistor is formed by stacking a control gate electrode above a floating gate electrode via an interelectrode insulating film. A poly-metal structure comprising a stack of metal film and polysilicon film is being considered for implementing the control gate electrode. However, the metal material used in the metal film may scatter during the manufacturing process flow and may influence the memory properties.

### BRIEF DESCRIPTION OF THE DRAWINGS

FIG. 1 is one example of a block diagram schematically illustrating an electrical configuration of a NAND Flash memory device.

FIG. 2 is one example of a planar layout of the memory cell region in part.

FIG. 3 illustrates one example of a structure and one phase of the manufacturing process flow of a NAND flash memory device of a first embodiment and is one schematic example of a cross-sectional view taken along line 3-3 of FIG. 2.

FIG. 4A is one schematic example of a cross-sectional view taken along line 4A-4A of FIGS. 2 and 3.

FIG. 4B is one schematic example of a cross-sectional view taken along line 4B-4B of FIGS. 2 and 3.

FIG. 5 illustrates an example of one phase of the manufacturing process flow of the NAND flash memory device of the first embodiment and is one schematic example of a cross-sectional view taken along line 3-3 of FIG. 2.

FIG. 6A is one schematic example of a cross-sectional view taken along line 4A-4A of FIG. 2.

FIG. 6B is one schematic example of a cross-sectional view taken along line 4B-4B of FIG. 2.

FIG. 7 illustrates an example of one phase of the manufacturing process flow of the NAND flash memory device of the first embodiment and is one schematic example of a cross-sectional view taken along line 3-3 of FIG. 2.

FIG. 8 illustrates an example of one phase of the manufacturing process flow of the NAND flash memory device of the first embodiment and is one schematic example of a cross-sectional view taken along line 3-3 of FIG. 2.

FIG. 9 illustrates an example of one phase of the manufacturing process flow of the NAND flash memory device of the first embodiment and is one schematic example of a cross-sectional view taken along line 3-3 of FIG. 2.

FIG. 10 illustrates an example of one phase of the manufacturing process flow of the NAND flash memory device of the first embodiment and is one schematic example of a cross-sectional view taken along line 3-3 of FIG. 2.

FIG. 11 illustrates an example of one phase of the manufacturing process flow of the NAND flash memory device of the first embodiment and is one schematic example of a cross-sectional view taken along line 3-3 of FIG. 2.

FIG. 12 illustrates an example of one phase of the manufacturing process flow of the NAND flash memory device of the first embodiment and is one schematic example of a cross-sectional view taken along line 3-3 of FIG. 2.

FIG. 13 illustrates an example of one phase of the manufacturing process flow of the NAND flash memory device of the first embodiment and is one schematic example of a cross-sectional view taken along line 3-3 of FIG. 2.

FIG. 14 illustrates one example of a structure and one phase of the manufacturing process flow of the NAND flash memory device of a second embodiment and is one schematic example of a cross-sectional view taken along line 3-3 of FIG. 2.

### DESCRIPTION

In one embodiment, a nonvolatile semiconductor storage device is disclosed. The nonvolatile semiconductor storage device includes a semiconductor substrate; a gate insulating film formed above the semiconductor substrate; memory cell transistors formed above the gate insulating film, the memory cell transistors including a memory cell gate electrode, the memory cell gate electrode including a floating gate electrode having a first conductive film, an interelectrode insulating film, a control gate electrode having a stack of second conductive film and a metal film, and a first insulating film disposed one over the other; a sidewall film disposed so as to cover at least sidewalls of the metal film; and a second insulating film covering the memory cell gate electrode and the sidewall film.

In one embodiment, a method of manufacturing a nonvolatile semiconductor device is disclosed. The method includes forming memory cell gate electrodes including at least a gate insulating film, a first conductive film, an interelectrode insulating film, a second conductive film, a metal film, and a first insulating film, stacked one over the other above a semiconductor substrate; forming a sacrificial film above the semiconductor substrate, the sacrificial film covering the memory cell gate electrode and having a planar surface; etching back the sacrificial film so that an upper surface of the sacrificial film is higher than an under surface of the second conductive film and lower than an upper surface of the second conductive film; forming a first film entirely across an underlying structure; anisotropically etching back the first film so as to form a sidewall film that covers at least sidewalls of the metal film; removing the sacrificial film; and cleaning metal contamination with a cleaning liquid.

### Embodiments

Embodiments are described hereinafter through a NAND flash memory application with references to the accompanying drawings. Elements that are identical in functionality and structure are identified with identical reference symbols. The drawings are not drawn to scale and thus, do not reflect the actual measurements of the features such as the correlation of thickness to planar dimensions and the relative thickness of different layers. Further, directional terms such as up, upper, upward, down, lower, downward, left, leftward, right, and rightward are used in a relative context with an assumption that the worked surface, on which circuitry is formed, of the later described semiconductor substrate faces up. Thus, the directional terms do not necessarily correspond to the directions based on gravitational acceleration.

### First Embodiment

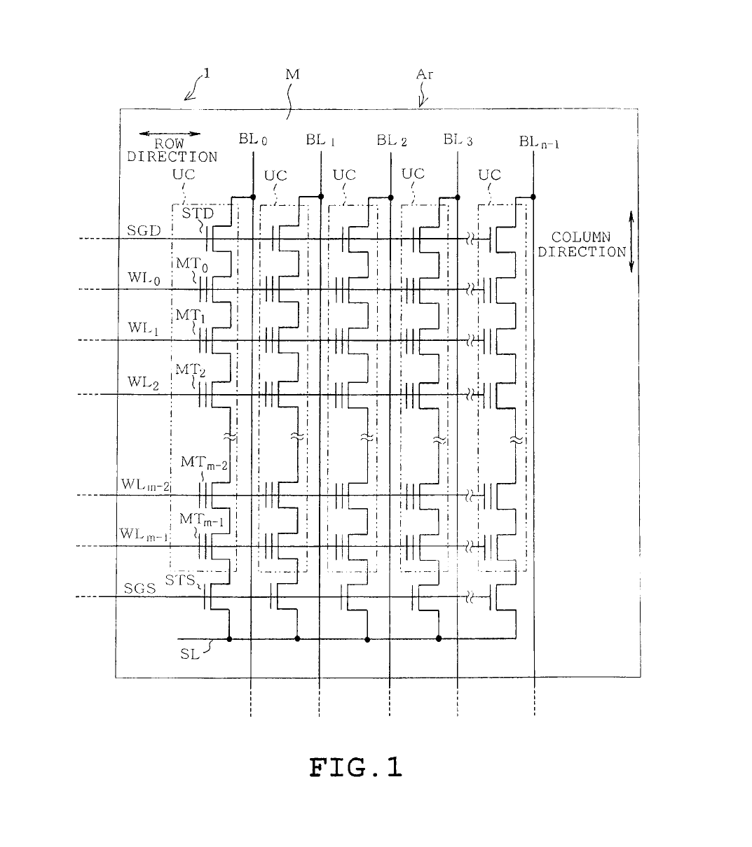

A description is given hereinafter on a first embodiment with reference to FIGS. 1 to 12.

FIG. 1 is one schematic example of an electrical configuration of NAND flash memory device 1 represented by a block diagram. As shown in FIG. 1, NAND flash memory device 1 is provided with memory cell array Ar in which multiplicity of memory cells are aligned in a matrix.

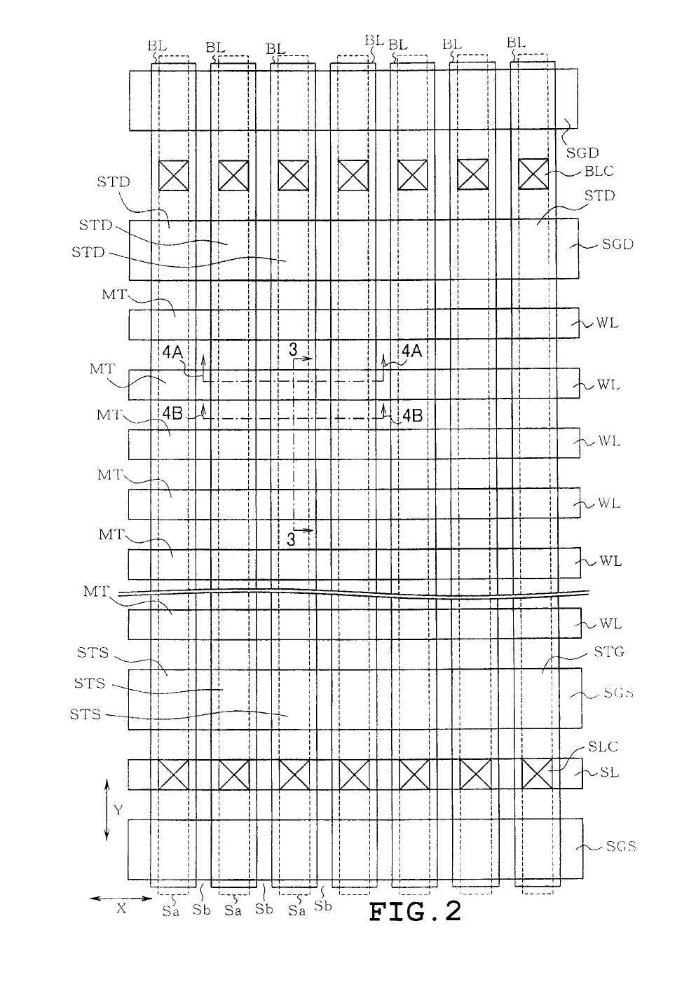

Memory cell array Ar located in memory cell region M includes multiplicity of units of cells referred to as unit memory cell UC. Unit memory cell UC comprises 2^{k}=m number of series connected memory-cell transistors MT₀ to MTₘ₋₁, such as 32 in number, situated between a couple of select transistors STD and STS that are located at Y-direction ends of unit memory cell UC as viewed in FIG. 2. Select transistors STD are connected to bit lines BL₀ to Blₙ₋₁, whereas select transistors STS are connected to source lines SL.

Multiple unit memory cells UC constitutes a memory-cell block and multiple memory-cell blocks, hereinafter also simply referred to as block/blocks, constitute memory cell array Ar. A single block comprises n number unit memory cells UC, aligned along the left and right direction or the row direction as viewed in FIG. 1. Memory cell array Ar is formed of multiple blocks aligned along the up and down direction or the column direction as viewed in FIG. 1. FIG. 1 only shows one block for simplicity.

The gates of select transistors STD are connected to control line SGD. The control gate electrodes of the m^{th} memory-cell transistors MTₘ₋₁ connected to bit lines BL₀ to Blₙ₋₁ are connected to word line WLₘ₋₁. The control gate electrodes of the third memory-cell transistors MT₂ connected to bit lines BL₀ to Blₙ₋₁ are connected to word line WL₂. The control gate electrodes of second memory-cell transistors MT₁ connected to bit lines BL₀ to Blₙ₋₁ are connected to word line WL₁. The control gate electrodes of first memory-cell transistors MT₀ connected to bit lines BL₀ to Blₙ₋₁ are connected to word line WL₀. The gates of select transistors STS connected to source lines SL are connected to control line SGS. Control lines SGD, word lines WL₀ to WLₘ₋₁, control lines SGS, and source lines SL each intersect with bit lines BL₀ to Blₙ₋₁. Bit lines BL₀ to Blₙ₋₁ are connected to a sense amplifier not shown.

Gate electrodes of select transistors STD of the row-directionally aligned unit memory cells UC are electrically connected by common control line SGD. Similarly, gate electrodes of select transistors STS of the row directionally aligned unit memory cells UC are electrically connected by common control line SGS. As described earlier, the source of each select transistor STS is connected to common source line SL. Gate electrodes of memory-cell transistors MT₀ to MTₘ₋₁ of the row-directionally aligned unit memory cells UC are each electrically connected by common word line WL₀ to WLₘ₋₁ respectively.

FIG. 2 is one schematic example of a planar layout of the memory cell region M in part. Bit lines BL₀ to Bₙ₋₁, word lines WL₀ to WLₘ₋₁, and memory-cell transistors MT₀ to MTₘ₋₁ are also hereinafter referred to as bit line(s) BL, word line(s) WL, and memory-cell transistor(s) MT for simplicity.

As shown in FIG. 2, source line SL, control line SGS, and control line SGD each run in the X direction and are spaced from one another in the Y direction. The Y direction is the up and down direction which is indicated as the column direction in FIG. 1, whereas the X direction is the left and right direction which is indicated as the row direction in FIG. 1. Bit lines BL each run in the Y direction and are spaced from one another in the X direction by a predetermined distance.

Element isolation regions Sb run in the Y direction. The isolation scheme being employed is an STI (shallow trench isolation) scheme in which trenches are filled with an insulating film. Element isolation regions Sb are spaced from one another in the X direction as viewed in FIG. 2 by a predetermined distance. Thus, element isolation regions Sb isolate element regions Sa, formed in a surface layer of semiconductor substrate 2 along the Y direction, in the X direction. In other words, element isolation region Sb is located between element isolation regions Sa, meaning that silicon substrate 2, is divided into a plurality of element regions Sa by element isolation region Sb.

Still referring to FIG. 2, multiplicity of word lines WL, spaced from one another in the Y direction by a predetermined distance, extend in the X direction which is the direction orthogonal to the Y direction in which element region Sa extend. Above element region Sa located at the intersection with word line WL, memory-cell transistor MT is formed. Similarly, above element region Sa located at the intersection with control lines SGS and SGD, select transistors STS and STD are formed. The Y-directionally adjacent memory-cell transistors MT constitute a part of a NAND string also referred to as a memory-cell string.

Select transistors STS and STD are typically provided on the Y-directional ends of the NAND string such that the Y-directionally adjacent memory-cell transistors MT are interposed between the pair of select transistors STS and STD.

As described earlier, select transistors STS connected to source line SL are aligned in the X direction and gate electrodes of select transistors STS are electrically interconnected by control line SGS. The gate electrode of select transistor STS is formed above element region Sa intersecting with control line SGS. Source contact SLC is provided at the intersection of source line SL and bit line BL.

Select transistors STD are aligned in the X direction and gate electrodes of select transistors STD are electrically interconnected by control line SGD. The gate electrode of select transistor STD is formed above element region Sa intersecting with control line SGD. Bit line contact BLC is provided in element region Sa located between the adjacent select transistors STD.

The fundamental structures of the NAND flash memory device of the first embodiment are as described above.

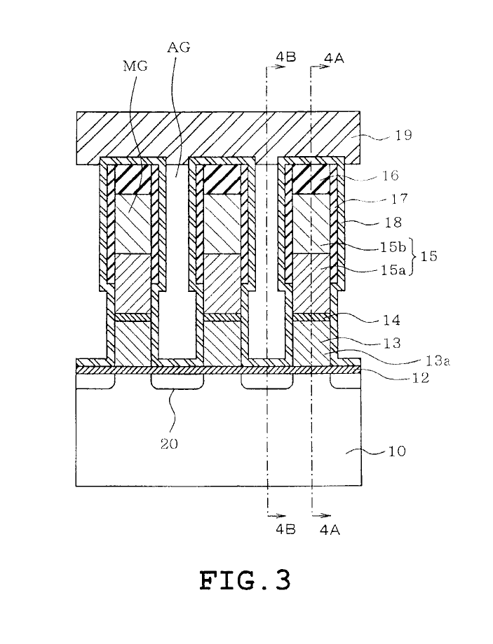

The structures of the first embodiment will be described in detail with reference to FIGS. 3 to 12. FIG. 3 is one example of a view schematically illustrating the structure of NAND flash memory device of the first embodiment. FIG. 3 is one schematic example of a cross sectional view taken along line 3-3 of FIG. 2.

As shown in FIG. 3, memory cell gate electrodes MG are disposed above semiconductor substrate 10. Semiconductor substrate 10 may comprise, for example, a P conductive-type silicon substrate. Gate insulating film 12 is formed above semiconductor substrate 10. Gate insulating film 12 may comprise, for example, a silicon oxide film formed by thermal oxidation.

Memory cell gate electrode MG is formed by stacking floating gate electrode 13, interelectrode insulating film 11, and control gate electrode 15 above gate insulating film 12. Floating gate electrode 13 may comprise, for example, a polysilicon film doped with impurities. The impurities may comprise, for example, phosphorous. Interelectrode insulating film 14 may comprise, for example, an ONO (Oxide Nitride Oxide film made of a stack of silicon oxide film/silicon nitride film/silicon oxide film. Control gate electrode 15 may comprise, for example, a stack of second polysilicon film 15a doped with impurities and metal film 15b stacked one over the other. The impurities doped into second polysilicon film 15a may comprise, for example, phosphorous. Metal film 15b may, for example, comprise tungsten (W) formed by CVD. Metal film 15b may include a barrier metal film in its lower portion, in other words, at the contacting interface with second polycrystalline silicon film 15a. The barrier metal film may comprise, for example, tungsten nitride (WN) formed by CVD. In such case, metal film 15b comprises, for example, a stack of tungsten nitride/tungsten. The barrier metal film is used, for example, to prevent reaction between polysilicon constituting second polysilicon film 15a and tungsten constituting metal film 15b.

Interelectrode insulating film 14 is provided between floating gate electrode 13 and control gate electrode 15. Floating gate electrode 13 and control gate electrode 15 are insulated from one another by interelectrode insulating film 14. Above control gate electrode 15, cap insulating film 16 is disposed which may comprise, for example, a silicon nitride film formed by CVD.

Sidewall film 17 extending along the upper half portion of the sidewalls of second polysilicon film 15a, the sidewalls of metal film 15b, and the sidewalls of cap insulating film 16 is disposed so as to cover the sidewalls of the foregoing films. Thus, at least the sidewalls of metal film 15b are covered by sidewall film 17. In the first embodiment, the sidewalls of metal film 15b are completely covered by sidewall film 17 which extends along the sidewalls of the films disposed above and below metal film 15b. Sidewall film 17 may comprise, for example, a silicon nitride film formed by CVD.

Liner insulating film 18 is disposed so as to cover the surfaces of gate insulating film 12, memory cell gate electrode MG, and sidewall film 17. Liner insulating film 18 may comprise, for example, an insulating film such as a silicon oxide film formed by CVD. Liner insulating film 18 is used as a protective film. At least the sidewalls of metal film 15b are covered by the stack of sidewall film 17 and liner insulating film 18. Thus, the thickness of the insulating film along the sidewalls of metal film 15b is the sum of the thickness of sidewall film 17 and liner insulating film 18. The thickness of the insulating film along the sidewalls of floating gate electrode 13 is the thickness of liner insulating film 18. Thus, the thickness of the insulating film along the sidewalls of metal film 15b is thicker than the thickness of the insulating film along the sidewalls of floating gate electrode 13. In other words, the distance from the sidewalls of metal film 15b to the surface of liner insulating film 18 is greater than the distance from the sidewalls of floating gate electrode 13 to the sidewalls of liner insulating film 18.

Gaps or unfilled gaps are formed between memory cell gate electrodes MG and plasma oxide film 19 covers the gaps so as to cap the gaps. The gaps between memory cell gate electrodes MG are hereinafter also referred to as air gap AG. Plasma oxide film 19 may comprise, for example, silicon oxide film formed by plasma CVD. Because plasma oxide film 19 is formed under conditions providing poor step coverage, air gap AG is not fully filled. Plasma oxide film 19 is formed so as to cover the upper portions of memory cell gate electrodes MG and the upper portions of air gaps AG. Air gaps AG reduce the parasitic capacitance between memory cell gate electrodes MG.

In the surface of semiconductor substrate 10 located on both sides of memory cell gate electrodes MG, source/drain region 20 is formed. Source/drain region 20 is an n-type diffusion layer region doped with impurities such as phosphorous.

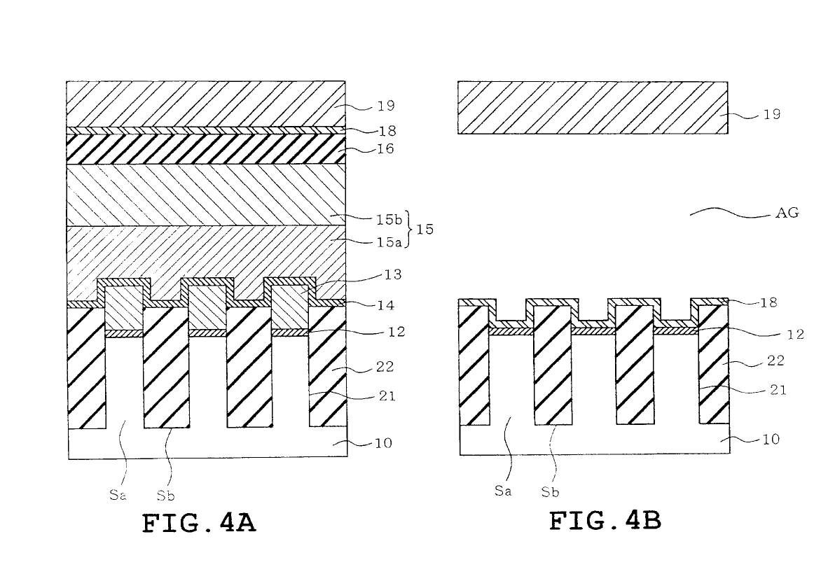

FIG. 4A illustrates one schematic example of a cross sectional structure taken along line 4A-4A of FIGS. 2 and 3. More specifically, FIG. 4A illustrates one example of a cross section of memory cell gate electrode MG taken along the direction in which memory cell gate electrodes MG extend (corresponding to the X direction in FIG. 2 and the row direction in FIG. 1).

Referring to FIG. 4A, element isolation trenches 21 having a predetermined width are formed into the surface of semiconductor substrate 10. Element isolation trenches 21 are filled with element isolation insulating film 22 to form element isolation regions Sb. Element regions Sa are isolated from one another in the left and right direction by element isolation regions Sb. Gate insulating film 12 is formed above the surface of semiconductor substrate 10 located in element region Sa and floating gate electrode 13 is formed above gate insulating film 12. Aforementioned element isolation insulating film 22 contacts the substantial lower half portion of the sidewalls of floating gate electrode 13. The substantial upper half portion of the sidewalls of floating gate electrode 13 as well as the upper surface of floating gate electrode 13 are covered by interelectrode insulating film 14. Interelectrode insulating film 14 is disposed above element isolation insulating film 22 and floating gate electrode 13. Control gate electrode 15 is disposed above floating gate electrode 13, interelectrode insulating film 14, and element isolation insulating film 22 via interelectrode insulating film 14 and extends continuously along the left and right direction of FIG. 4A. Above control gate electrode 15, cap insulating film 16, liner insulating film 18, and plasma oxide film 19 are stacked one over the other.

FIG. 4B illustrates one schematic example of a cross sectional structure taken along line 4B-4B of FIGS. 2 and 3. More specifically, FIG. 4B illustrates one example of a cross section of the gap between memory cell gate electrodes MG taken along a direction parallel to the cross section of FIG. 4A.

Referring to FIG. 4B, element isolation trenches 21 having a predetermined width are formed into the surface of semiconductor substrate 10. Element isolation trenches 21 are filled with element isolation insulating film 22 to form element isolation regions Sb. Element regions Sa are isolated from one another in the left and right direction as viewed in FIG. 4B by element isolation regions Sb. Gate insulating film 12 is formed above the surface of semiconductor substrate 10 located in element region Sa. Liner insulating film 18 is formed above gate insulating film 12 and element isolation insulating film 22. Air gap AG exists above liner insulating film 18 and plasma oxide film 19 is disposed above air gap AG.

In the first embodiment, at least the sidewalls of metal film 15b are covered by sidewall film 77. Thus, it is possible to prevent dispersion of the metal material, such as tungsten, forming metal film 15b during manufacturing process flow. Thus, it is possible to prevent structures such as gate insulating film 12, floating gate electrode 13, and interelectrode insulating film 14 from being contaminated by metal materials. As a result, degradation of memory properties can be inhibited to provide a reliable nonvolatile semiconductor storage device.

### <Manufacturing Method>

Next, a description will be given on one example of a manufacturing process flow of the nonvolatile semiconductor storage device. The following descriptions will focus on the features according to one embodiment and thus, known steps may be added to the process flow as required. Further, the sequence of the process flow may be rearranged if practicable.

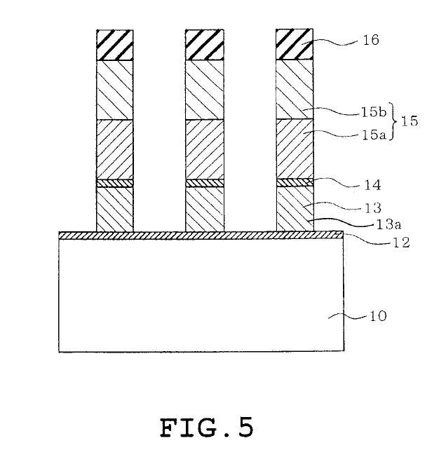

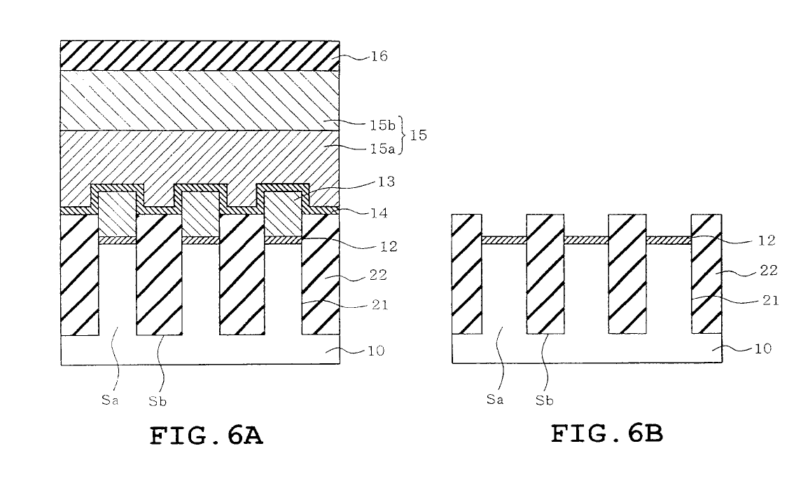

FIG. 5 exemplifies one process step of the manufacturing process flow of a NAND flash memory device of the first embodiment and is one example of a cross sectional view taken along line 3-3 of FIG. 2. FIG. 6A illustrates the same process step and is one example of a cross sectional view taken along line 4A-4A of FIG. 2. FIG. 6A illustrates one example of a cross section of memory cell gate electrode MG taken along the direction in which memory cell gate electrodes MG extend (which corresponds to the X direction in FIG. 2 and the row direction in FIG. 1).

FIG. 6B illustrates the same process step and is one example of a cross sectional view taken along line 4B-4B of FIG. 2. FIG. 6B illustrates one example of a cross section of the gap between memory cell gate electrodes MG taken along a direction parallel to the cross section of FIG. 6A.

First a brief description will be given on the process flow for obtaining the structures illustrated in FIGS. 5, 6A, and 6B. Gate insulating film 12, first polysilicon film 13a (serving as floating gate electrode 13), and mask nitride film are formed above semiconductor substrate 10 and patterned by dry etching using lithography and RIE (Reactive Ion Etching). In this process step, etching progresses into semiconductor substrate 10 and forms element isolation trenches 21. Silicon oxide film (serving as element isolation insulating film 22) is formed throughout the entire surface to overfill element isolation trenches 21 and the gaps between floating gate electrode 13. The silicon oxide film is polished by CMP (Chemical Mechanical Polishing) so as to be substantially level with the upper surface of mask nitride film. Then, the height of the upper surface of the silicon oxide film is lowered to a predetermined height located at substantially mid height of floating gate electrode 13. The mask nitride film is removed by phosphoric acid (hot phosphoric acid) heated, for example, to approximately 140 degrees Celsius. Element isolation insulating film 22 is thus formed and the region in which element isolation film 22 is formed serves as element isolation region Sb. As described above, semiconductor substrate 10 may comprise a P conductive type silicon substrate as mentioned earlier. Gate insulating film 12 may be formed for example by thermally oxidizing the surface of semiconductor substrate 10 in a dry O₂ ambient at the temperature of 950 degrees Celsius. First polysilicon film 13a may be formed by forming polysilicon film by methods such as CVD (Chemical Vapor Deposition) and doping impurities such as phosphorous into the polysilicon film.

Referring to FIGS. 5, 6A, and 6B, interelectrode insulating film 14, control gate electrode 15, and cap insulating film 16 are formed. Interelectrode insulating film 14 may comprise an ONO film as described earlier. ONO film may be formed, for example, by depositing silicon oxide film, silicon nitride film, and silicon oxide film one over the other by CVD. Control gate electrode 15 is formed by stacking second polysilicon film 15a and metal film 15b one over the other. Metal film 15b may be formed as a stack including a barrier metal film in its lower layer. Second polysilicon 15a may be formed by doping impurities such as phosphorous by ion implantation into a polysilicon formed, for example, by CVD. Metal film 15b may comprise, for example tungsten formed by CVD. When forming metal film 15b as a stack of barrier metal film and metal film, the barrier metal film may be formed, for example, by depositing tungsten nitride by CVD, whereafter tungsten is deposited, for example, by CVD. Cap insulating film 16 may comprise, for example, a silicon nitride film formed by CVD. Cap insulating film 16 may comprise a silicon oxide film instead of a silicon nitride film. Then, cap insulating film 16, metal film 15b, second polysilicon film 15a, interelectrode insulating film 14, and floating gate electrode 13 are etched one after another by lithography and RIE. Memory cell gate electrode MG is formed by the above described process flow.

The dry etching of memory cell gate electrode MG may cause attachment of re-deposits on the sidewalls of memory cell gate electrode MG and the surface of semiconductor substrate 10. Thus, cleaning is carried out in order to remove the re-deposits. A cleaning liquid including dilute hydrofluoric acid, for example, may be used in removing oxide film based re-deposits. A cleaning liquid including excess ammonia aqueous solution or excess choline aqueous solution, for example, may be used in removing metal based (tungsten based) re-deposits.

Next, a description will be given on the effects of the cleaning liquids described above. The cleaning liquid including dilute hydrofluoric acid is effective in removing oxide film based re-deposits. The cleaning liquid including excess ammonia aqueous solution or excess choline aqueous solution is effective in removing metal based (tungsten based) re-deposits. The cleaning liquid including excess ammonia aqueous solution or excess choline aqueous solution is effective in removing surface metal contamination. The cleaning liquid including excess ammonia aqueous solution or excess choline aqueous solution is further effective in causing elution of metal material. This elution of metal material enables the removal of metal contamination. When the sidewalls of metal film 15b of memory cell gate electrode MG are exposed, the cleaning liquid contacts metal film 15b and causes the metal material constituting metal film 15b to elute into the cleaning liquid. The metal material forming metal film 15b is a material that dissolves into the cleaning liquid including excess ammonia aqueous solution or excess choline aqueous solution. The metal material eluted into the cleaning liquid may attach to other portions of memory cell gate electrode MG or may reattach to the surface of semiconductor substrate 10. In other words, when the cleaning is carried out with metal film 15b exposed, there may be greater amount of re-attachment of eluted metal compared to the amount of removal of metal material attached to the surfaces of the semiconductor substrate 10, etc. When metal film 15b comprises tungsten, tungsten elutes into the cleaning liquid. As a result, other portions of memory cell gate electrode MG or the surfaces of semiconductor substrate 10, etc. may be contaminated by tungsten. The same is applicable when a barrier metal film is provided in metal film 15b and the barrier metal includes metal material. When the barrier metal film comprises, for example, a tungsten nitride, tungsten elutes into the cleaning liquid. As a result, other portions of memory cell gate electrode MG or the surface of semiconductor substrate 10 may be contaminated by tungsten.

When the NAND flash memory device is used with metal attachments, caused by the above described metal contamination, on the surfaces of structures such as floating gate electrode 13, gate insulating film 12, and interelectrode insulating film 14, the following behavior is observed. Electrons injected into floating gate electrode 13 are easily released from floating gate electrode 13 by the influence of the attached metal. As a result, it becomes difficult to retain the electrons in floating gate electrode 13 which in turn makes it difficult for the NAND flash memory device to retain data.

The first embodiment realizes a structure for preventing the above described behavior by the following process flow. The description of the manufacturing process flow will continue below.

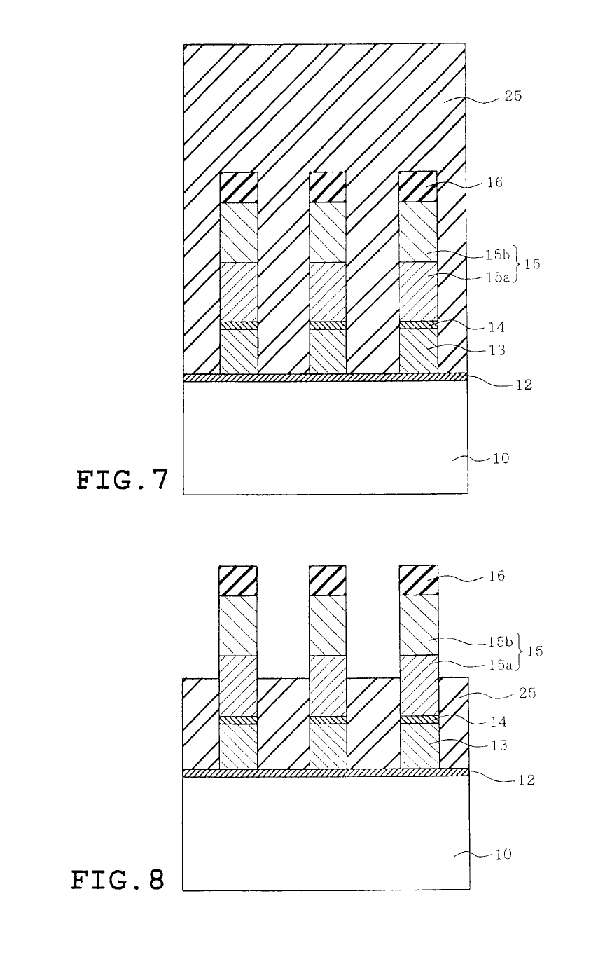

As shown in FIG. 7, resist film 25 serving as a sacrificial film is coated throughout the entire surface. Resist film 25 is developed without being exposed so as to harden. Resist film 25 covers memory cell gate electrodes MG and is formed to have a planar upper surface.

As shown in FIG. 8, resist film 25 is etched back so that the height of the upper surface of resist film 25 is higher than the under surface of second polysilicon film 15a but lower than the upper surface of second polysilicon film 15a. The etch back may be carried out, for example, by anisotropic dry etching using RIE and O₂ plasma. The end point of the etching is controlled, for example, by monitoring the variation in the wavelength of light irradiated from plasma produced during the etching. More specifically, the variation in the wavelength of plasma light is detected at the moment cap insulating film 16 is exposed, and this moment in time is defined as the first end point. The time point after lapse of predetermined time period after the first end point is defined as the second end point. The etching is configured to continue after the first end point has elapsed and to stop when the second end point has elapsed. It is possible to control the height of the upper surface of resist film 25 by controlling the time period from the first endpoint to the second end point.

In an alternative embodiment, it is possible to control the height of the upper surface of resist film 25 by etching resist film 25 with SPM (Sulfuric Acid Hydrogen Peroxide Mixture). SPM comprises a mixture of sulfuric acid and hydrogen peroxide solution and is referred to as sulfuric acid hydrogen peroxide. The height of the upper surface of resist film 25 is controlled through adjustment of the duration of SPM processing.

Resist film 25 serving as the sacrificial film may be replaced by a carbon film or a BSG (Boron Silicate Glass) film. The carbon film may be formed, for example, by plasma CVD. Carbon film may be etched back by dry etching using O₂ plasma and RIE. Carbon film may be removed, for example, by asking using O₂ plasma. BSG film may be formed, for example, by CVD. BSG film may be etched back by dry etching using RIE or by vapor phase HF. BSG film may be removed, for example, by vapor phase HF.

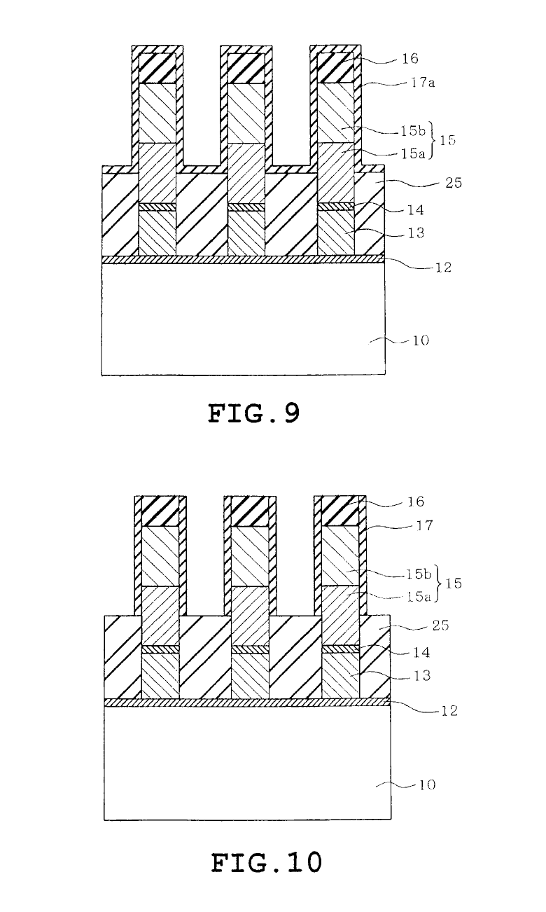

As shown in FIG. 9, film 17a is formed which is later formed into sidewall film 17. Film 17a is formed under conditions providing good step coverage. Film 17a is formed conformally along the exposed surfaces of cap insulating film 16, metal film 15b, and second polysilicon film 15a with good step coverage. Film 17a may comprise any material that is not etched by the cleaning liquid in the cleaning step carried out later in the process flow. A material which is etched by the cleaning liquid may be used as long as the material remains at least throughout the cleaning process. If film 17a is dissolved by the cleaning liquid during the cleaning step carried out later in the process flow, the thickness of film 17a may be controlled to a thickness which is at least not completely dissolved away during the cleaning step. The thickness of the material is preferably greater than such thickness. Further, the thickness of film 17a is controlled to a thickness which at least does not close the gaps between the adjacent memory cell gate electrodes MG. Film 17a may comprise, for example, a silicon nitride film. The silicon nitride film may be formed, for example, by a low temperature ALD (Atomic Layer Deposition).

As shown in FIG. 10, film 17a is anisotropically dry etched by RIE. As a result, the planar portions of film 17a are removed while the portions extending along sidewalls of cap insulating film 16, the sidewalls of metal film 15b, and the sidewalls of second polysilicon film 15a uncovered by resist film 25 remain. Sidewall film 17 covering the sidewalls of the foregoing structures are thus, formed.

Because cap insulating film 16 and sidewall film 17 both comprise a silicon nitride film, there is no difference in their etching rates. Thus, as shown in FIG. 10, the upper portions oft cap insulating film 16 and sidewall film 17 are planar.

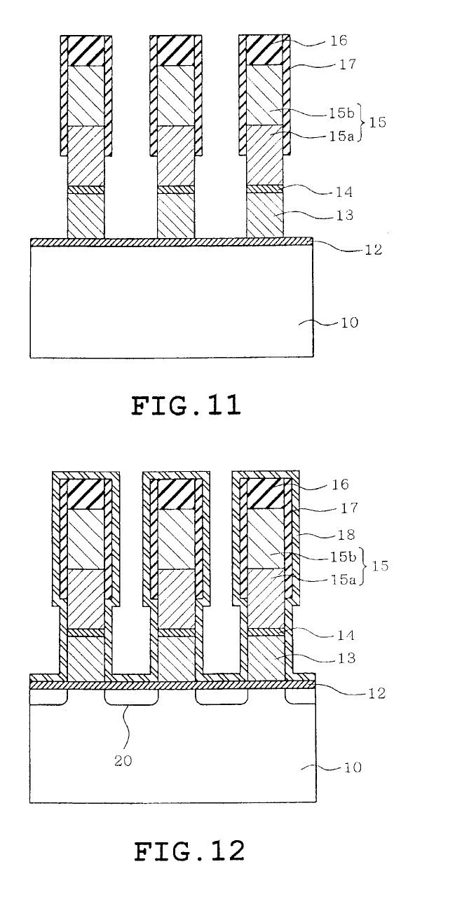

As shown in FIG. 11, resist film 25 is removed. Resist film 25 may be removed by ashing using O₂ plasma or by SPM. The above described process flow forms sidewall film 17 extending along the sidewalls of cap insulating film 16, the sidewalls of metal film 15b, and the substantial upper half portions of the sidewalls of second polysilicon film 15a. Sidewall film 17 covers at least the sidewalls of metal film 15b. When metal film 15b comprises a stack of tungsten nitride and tungsten, sidewall film 17 covers the sidewalls of metal film 15b including tungsten nitride and tungsten. Sidewall film 17 further covers the substantial upper half portions of the sidewalls of second polysilicon film 15a located below metal film 15b. Sidewall film 17 is formed to extend along not only the sidewalls of metal film 15b but also along the sidewalls of films located above and below metal film 15b to ensure that the sidewalls of metal film 15b are sufficiently covered.

The surface of semiconductor substrate 10 is cleaned for example by a clean liquid including, excess ammonia aqueous solution or excess choline aqueous solution. It is possible to remove metal contamination from the surface of semiconductor substrate 10 by the cleaning. Sidewall film 17 covers at least the sidewalls of metal film 15b and further extends along the sidewalls of cap insulating film 16 and second polysilicon film 15a disposed above and below metal film 15b. Because, metal film 15b being covered by sidewall film 17 is not exposed, the cleaning liquid does not contact metal film 15b. As a result, the metal material of metal film 15b does not elute into the cleaning liquid during the cleaning step. For example, when the metal material used in metal film 15b is tungsten, the cleaning liquid does not contact tungsten. Thus, tungsten does not elute into the cleaning liquid during the cleaning process.

As described above, metal contamination is removed from the surface of semiconductor substrate 10 by the cleaning. The cleaning will not cause the metal material of metal film 15b to elute into the cleaning liquid. Thus, there will be no instances of metal material of metal film 15b eluting into the cleaning liquid and re-attaching to other portions through the cleaning liquid.

Metal which may have been attached to the surfaces of memory cell gate electrodes MG and semiconductor substrate 10 in the etching of memory cell gate electrodes MG carried out in the process steps illustrated in FIGS. 5, 6A, and 6B is removed in the cleaning step. Thus, it is possible to remove the metal material attached to the sidewalls of floating gate electrode 13, interelectrode insulating film 14, and gate insulating film 12 by the cleaning and provide a metal-contamination free structure.

Liner insulating film 18 is formed throughout the entire surface with good step coverage so as to conform to the surface profiles of memory cell gate electrodes MG covered by sidewall film 17 and semiconductor substrate 10. Liner insulating film 18 may comprise, for example, a silicon oxide film formed by CVD. The thickness of the insulating film along the sidewalls of metal film 15b is greater than the thickness of the insulating film along the sidewalls of floating gate electrode 13 because of sidewall film 17 formed at least along the sidewalls of metal film 15b. This means that the distance from the sidewalls of metal film 15b to the surface of liner insulating film 18 is greater than the distance from the sidewalls of floating gate electrode 13 to the surface of liner insulating film 18.

Then, phosphorous, for example, may be introduced into the surface of semiconductor substrate 10 by ion implantation at acceleration of 20 Kev and in the dose of 5×10¹⁴ atms/cm². Thus, source/drain region 20 is formed into the surface of semiconductor substrate 10 located between memory cell gate electrodes MG.

As shown in FIG. 3, plasma oxide film 19 is formed throughout the entire surface. Plasma oxide film 19 may comprise, for example, a silicon oxide film formed by plasma CVD under conditions providing poor step coverage.

As a result, it is possible to cover the gaps between memory cell gate electrodes MG like a cap without filling the gaps. Plasma oxide film 19 is formed so as to extend across the upper surfaces of memory cell gate electrodes MG without filling the gaps between memory cell gate electrodes MG so as to cover the entire upper surfaces of memory cell gate electrodes MG.

Thus, the gaps between memory cell gate electrodes MG are sealed off by plasma oxide film 19 to form air gaps AG. NAND flash memory device 1 of the first embodiment is formed by the above described process flow.

In the first embodiment described above, sidewall film 17 covers at least the sidewalls of metal film 15b and further extends along the sidewalls of the films above and below metal film 15b. Because the sidewalls of metal film 15b are covered by sidewall film 17 and thus, not exposed, metal material does not elute into the cleaning liquid even when cleaned in this state.

In the first embodiment, it is possible to inhibit metal contamination and provide a nonvolatile semiconductor storage device having outstanding memory properties and a method of manufacturing such nonvolatile semiconductor storage device.

### Second Embodiment

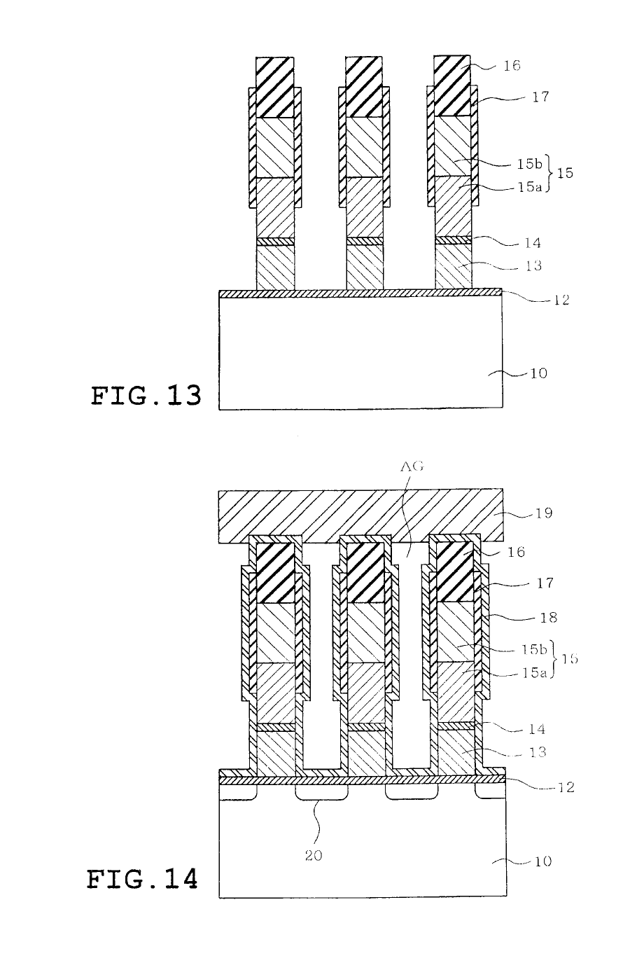

A description will be given on a second embodiment with reference to FIGS. 13 and 14. In the second embodiment, silicon oxide film or silicon (polysilicon) film is used as sidewall film 17 (film 17a) instead of silicon nitride film. In such case, the shape of the resulting structure differs from the shape of the first embodiment. In the second embodiment, sidewall film 17 covers the sidewalls of metal film 15b and substantially the upper half portions of the sidewalls of second polysilicon film 15a located below metal film 15b. This remains the same from the first embodiment. The second embodiment differs from the first embodiment in that, sidewall film 17 covers substantially the lower half portions of the sidewalls of cap insulating film 16 located above metal film 15b.

The manufacturing process flow for obtaining the structure of the second embodiment will be given hereinafter. The process steps up to FIG. 8 of the first embodiment are carried out. In the process step illustrated in FIG. 9, film 17a is formed by a silicon oxide film or a silicon film. Film 17a is formed conformally along the exposed portions of cap insulating film 16, metal film 15b, and second polysilicon film 15a and along the surface of resist film 25 with good step coverage. This remains the same from the first embodiment. The silicon oxide film may be formed by low temperature ALD. The silicon film may be formed by low temperature CVD. Polysilicon or amorphous silicon may be used as the silicon film. The thickness of film 17a may be controlled to a thickness which is at least not dissolved away during the cleaning step carried out later in the process flow. The thickness of the material is preferably greater than such thickness. Further, the thickness of film 17a is controlled to a thickness which at least does not close the gaps between the adjacent memory cell gate electrodes MG.

As shown in FIG. 13, film 17a is anisotropically dry etched throughout the entire surface by RIE. As a result, the planar portions of film 17a are removed while the portions extending along the sidewalls of cap insulating film 16, the sidewalls of metal film 15b, and the substantial upper portions of sidewalls of second polysilicon film 15a remain in the form of a sidewall. Sidewall film 17 covering the sidewalls of the foregoing structures are thus, formed.

Film 17a comprises a silicon oxide film or a silicon film and thus, the etch rate differs from the etch rate of cap insulating film 16 comprising a silicon nitride film. Thus, it is possible to selectively etch film 17a without significantly receding cap insulating film 16. The thickness of cap insulating film 16 in the resulting structure will be greater in the second embodiment than in the first embodiment provided that cap insulating film 16 is formed in the same thickness in the first and the second embodiments. Thus, the upper portion of sidewall film 17 is lower in elevation compared to the upper portion of cap insulating film 16, and as shown in FIG. 13, sidewall film 17 covers the substantial lower half portion of cap insulating film 16.

As described above, because the sidewalls of metal film 15b are covered by sidewall film 17 and thus, not exposed, metal material does not elute into the cleaning liquid during the cleaning step carried out later in the process flow. Thus, it is possible to remove the metal material attached to the sidewalls of floating gate electrode 13, interelectrode insulating film 14, and gate insulating film 12 by the cleaning and provide a metal-contamination free structure.

After carrying out the process step described based on FIG. 12 of the first embodiment, the second embodiment forms plasma oxide film 19 as shown in FIG. 14 to form air gaps AG between memory cell gate electrodes MG. NAND flash memory device 1 of the second embodiment is formed by the above described process flow.

The second embodiment described above provides the advantages similar to those of the first embodiment and further ensures that the upper portion of memory cell gate electrodes MG are sufficiently covered by the thick cap insulating film 16.

### OTHER EMBODIMENTS

The foregoing embodiments may be modified as follows.

ONO film was given as one example of interelectrode insulating film 14, however, other films such as a NONON (nitride-oxide-nitride-oxide-nitride) film or an insulating film having high dielectric constant may be used instead.

Tungsten was given as one example of a metal material constituting metal film 15b, however, aluminum (AL) or titanium (Ti) may be used instead. Aluminum or titanium may be formed, for example, by CVD.

The above described embodiments were directed to NAND flash memory device, however, other embodiments may be directed to other nonvolatile semiconductor storage devices such as NOR flash memory and EERROM.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor storage device, comprising:
a semiconductor substrate;
a gate insulating film formed above the semiconductor substrate;
memory cell transistors formed above the gate insulating film, the memory cell transistors including a memory cell gate electrode, the memory cell gate electrode including a floating gate electrode having a first conductive film, an interelectrode insulating film, a control gate electrode having a stack of second conductive film and a metal film, and a first insulating film disposed one over the other;
a sidewall film disposed so as to cover at least sidewalls of the metal film; and
a second insulating film covering the memory cell gate electrode and the sidewall film.

2. The device according to claim 1, wherein the sidewall film further covers at least portions of sidewalls of the second conductive film, and at least portions of the sidewalls of the first insulating film.

3. The device according to claim 1, wherein the sidewall film comprises a silicon nitride film or a silicon oxide film or a silicon film.

4. The device according to claim 1, wherein the metal film comprises tungsten or aluminum or titanium.

5. The device according to claim 4, further comprising a barrier metal.

6. The device according to claim 1, wherein a distance from the sidewall of the metal film to a surface of the second insulating film is greater than a distance from a sidewall of the first conductive film to a surface of second insulating film.

7. The device according to claim 1, wherein gaps are provided between the memory cell gate electrodes.

8. The device according to claim 1, wherein the first insulating film comprises a silicon nitride film.

9. The device according to claim 1, wherein the second insulating film comprises a silicon oxide film.

10. A method of manufacturing a nonvolatile semiconductor device, comprising:
forming memory cell gate electrodes including at least a gate insulating film, a first conductive film, an interelectrode insulating film, a second conductive film, a metal film, and a first insulating film, stacked one over the other above a semiconductor substrate;
forming a sacrificial film above the semiconductor substrate, the sacrificial film covering the memory cell gate electrode and having a planar surface;
etching back the sacrificial film so that an upper surface of the sacrificial film is higher than an under surface of the second conductive film and lower than an upper surface of the second conductive film;
forming a first film entirely across an underlying structure;
anisotropically etching back the first film so as to form a sidewall film that covers at least sidewalls of the metal film;
removing the sacrificial film; and
cleaning metal contamination with a cleaning liquid.

11. The method according to claim 10, wherein the sidewall film further covers at least portions of sidewalls of the second conductive film, and at least portions of the sidewalls of the first insulating film.

12. The method according to claim 10, wherein the sidewall film comprises a silicon nitride film or a silicon oxide film or a silicon film.

13. The method according to claim 10, wherein the metal film comprises tungsten or aluminum or titanium.

14. The method according to claim 13, wherein the metal film further comprises a barrier metal.

15. The method according to claim 10, wherein gaps are formed between the memory cell gate electrodes.

16. The method according to claim 10, wherein the sacrificial film comprises a resist film or a carbon film or a boron silicate glass film.

17. The method according to claim 10, wherein the first insulating film comprises a silicon nitride film.

18. The method according to claim 10, wherein after at least forming the sidewall film, forming a second insulating film covering the memory cell gate electrodes and the sidewall film.

19. The method according to claim 18, wherein a distance from a sidewall of the metal film to a surface of the second insulating film is greater than a distance from a sidewall of the first conductive film to a surface of second insulating film.

20. The method according to claim 19, wherein the second insulating film comprises a silicon oxide film.
